(19) United States
(12) Patent Application Publication
(10) Pub. No.: US 2013/0234572 A1
(43) Pub. Date: Sep. 12, 2013

(54) COMPUTER ENCLOSURE

(71) Applicant: SHENG-CHIEH HSU, Tu-Cheng (TW)

(72) Inventor: SHENG-CHIEH HSU, Tu-Cheng (TW)

(73) Assignee: HON HAI PRECISION INDUSTRY CO., LTD., Tu-Cheng (TW)

(21) Appl. No.: 13/454,031

(22) Filed: Apr. 23, 2012

(30) Foreign Application Priority Data
Mar. 9, 2012 (TW) 101108084

(51) Int. Cl. H05K 5/03; H05K 7/18

(52) U.S. Cl. 312/223.2

(57) ABSTRACT

A computer enclosure includes a chassis and a number of supporting members. The chassis includes a bottom wall and two opposite sidewalls. A number of receiving slots are defined in a junction of the bottom wall and each sidewall. A pole extends from the chassis toward each receiving slot. Each supporting member is rotatably mounted to the pole. An inner wall of each receiving slot forms two positioning portions. A latching portion extends out from the rotating portion, to engage with one of the positioning portions.

### BACKGROUND

1. Technical Field

The present disclosure relates to a computer enclosure.

2. Description of Related Art

Personal computers generally includes two types: tower computers and desktop computers. Due to the trend towards miniaturization, a tower computer is made thinner than before. Because of this the tower computer may be unstable once it has been positioned. It is important to provide stands for supporting the tower computer in a more stable manner.

A conventional stand, such as a stand disclosed in U.S. Pat. No. 6,364,278, includes two coupled supporting members. Each supporting member includes a dove-tail shaped protrusion to couple with a recess of the other supporting member. However, a clamping ledge is integrally formed from each supporting member. Therefore, once the stand is assembled to the computer chassis, a large space is occupied, which makes the stand inconvenient to transport or to pack.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a partial, exploded, and isometric view of an exemplary embodiment of a computer enclosure.

FIG. 2 is an inverted view of FIG. 1.

FIG. 3 is an assembled, isometric view of FIG. 1.

FIG. 4 is similar to FIG. 3, but showing the computer enclosure in use.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

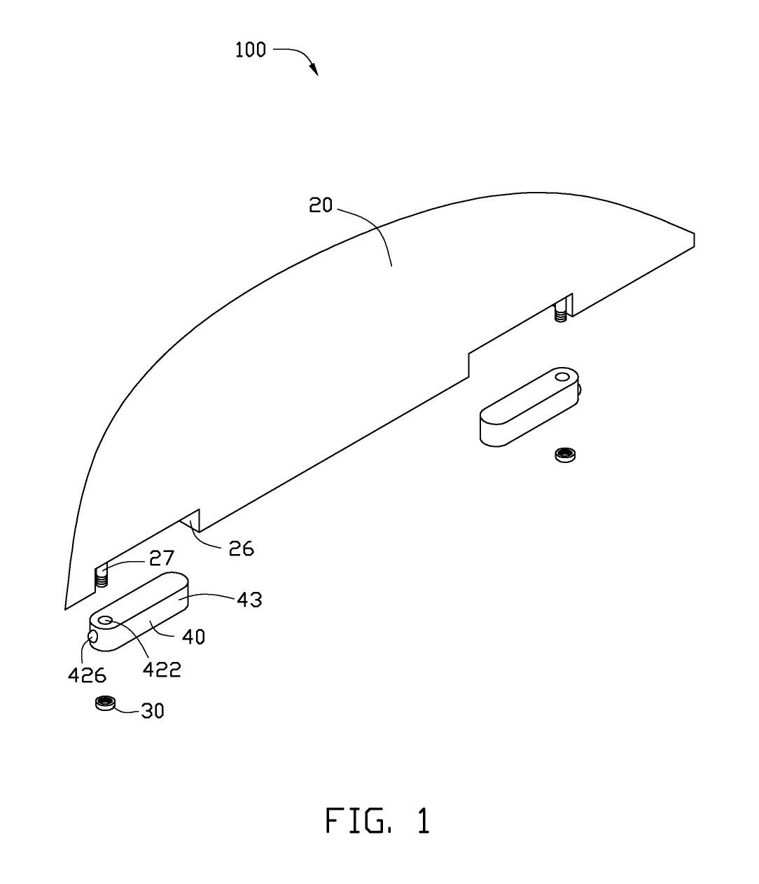

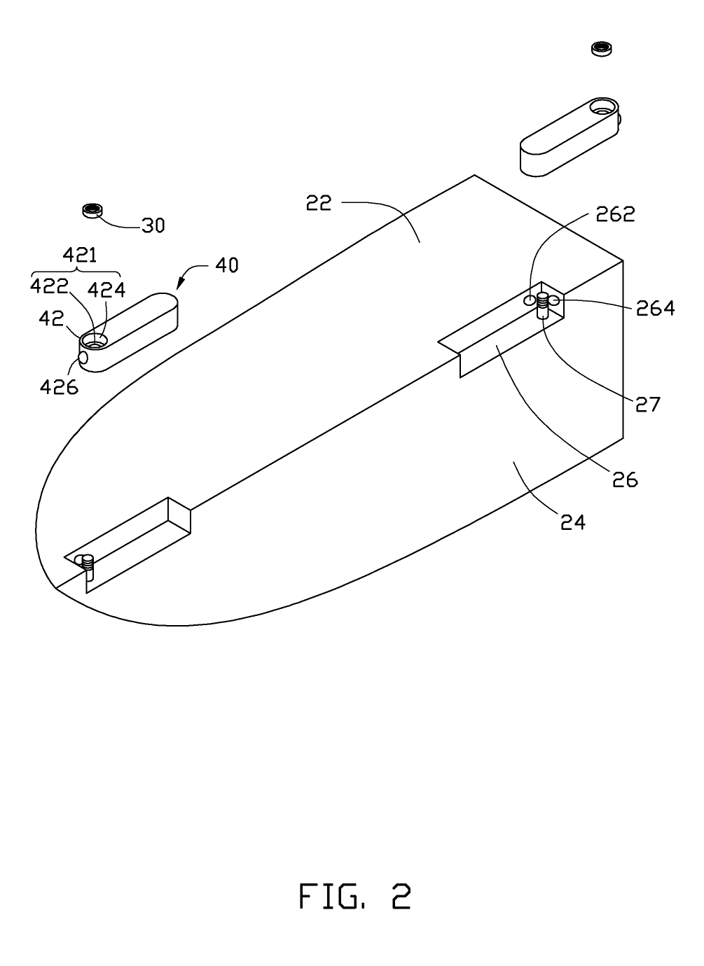

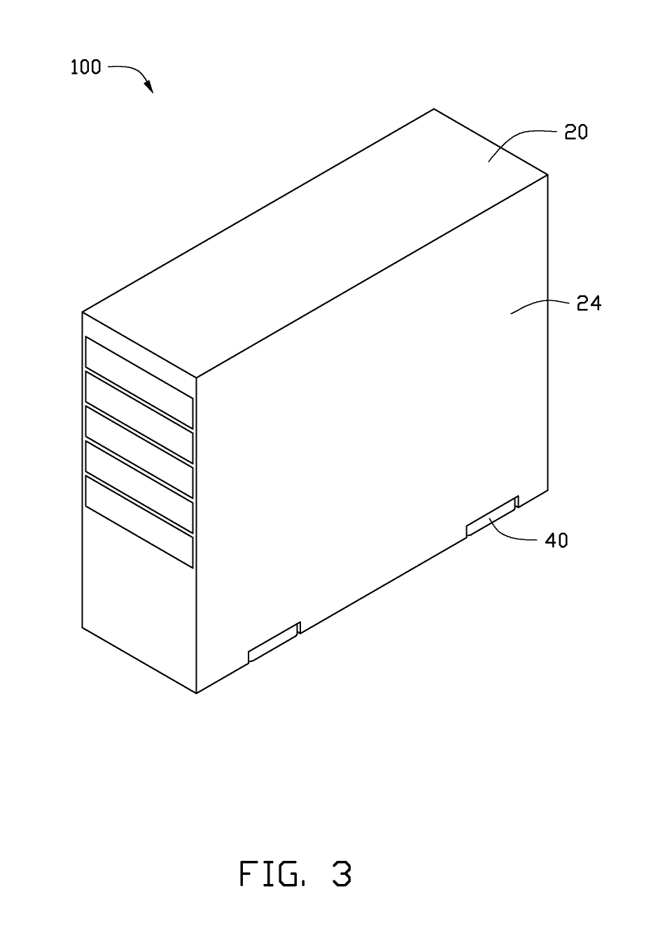

FIGS. 1 and 2, show an exemplary embodiment of a computer enclosure 100 including a chassis 20 (shown as FIG. 3), four nuts 30, and four supporting members 40. The chassis 20 includes a rectangular bottom wall 22, and two sidewalls 24 perpendicularly extending up from two opposite sides of the bottom wall 22. The bottom wall 22 and the sidewalls 24 cooperatively bound a receiving space to accommodate electronic components (not shown), such as a motherboard, a power supply, and a hard disk drive. Two rectangular receiving slots 26 are defined in a junction of the bottom wall 22 and each sidewall 24. A pole 27 extends down from an end of a top wall of each receiving slot 26. A distal end of the pole 27 is threaded. A sidewall of each receiving slot 26 defines a depressed first positioning portion 262, adjacent to the corresponding pole 27. An end wall of each receiving slot 26 defines a depressed second positioning portion 264 adjacent to the corresponding pole 27.

Each supporting member 40 is substantially rectangular, and includes an arc-shaped rotating portion 42 formed at a first end of the supporting member 40, and a supporting portion 43 formed at a second end of the supporting member 40 opposite to the rotating portion 42. A middle of the rotating portion 42 defines a stepped hole 421. The stepped hole 421 includes a first hole 422 extending through a top surface of the supporting member 40, and a second hole 424 extending through a bottom surface of the supporting member 40 communicating with the first hole 422. A diameter of the first hole 422 is less than a diameter of the second hole 424. A resilient latching portion 426 protrudes out from an end surface of the rotating portion 42, opposite to the supporting portion 43.

In the embodiment, the first and second positioning portions 262 and 264 are two hemispherical recesses. The latching portion 426 is a substantially hemispherical protrusion.

Referring to FIG. 3, in assembly, each pole 27 is inserted into the corresponding stepped hole 421 from the first hole 422, the distal end of the pole 27 is received in the corresponding second hole 424. Each nut 30 is screwed to the corresponding pole 27, and is received in the corresponding second hole 424. Each supporting member 40 is rotatable relative to the pole 27, thus the supporting member 40 can be received in or moved out of the corresponding receiving slot 26. The latching portion 426 of each supporting member 40 is positioned in either the first positioning portion 262 or the second positioning portion 264, to respectively keep the supporting member 40 in a first position where the supporting member 40 extends out of the receiving space 26 to support the chassis 20, in a second position where the supporting member 40 is received in the receiving space 26.

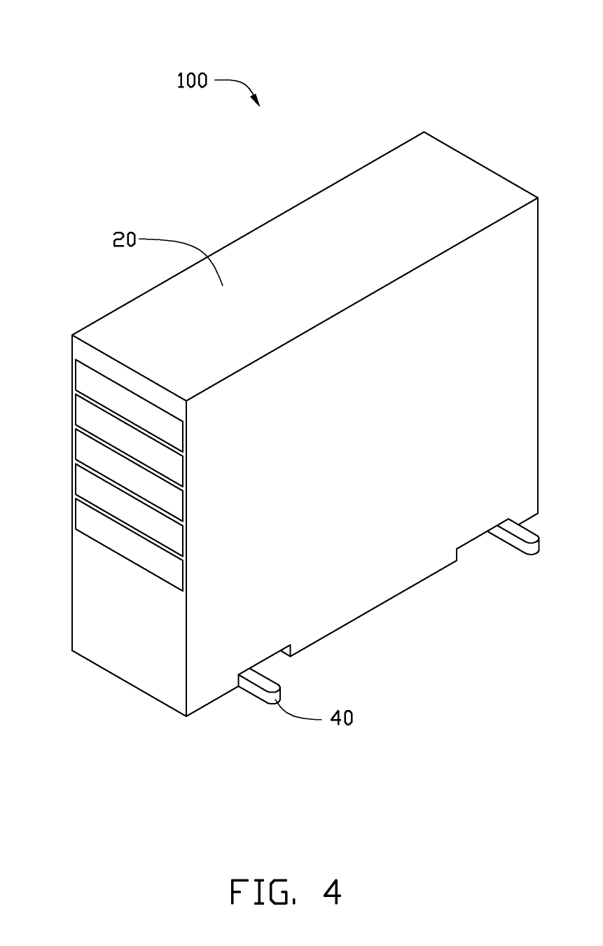

Referring to FIG. 4, in use, the supporting portion 43 of each supporting member 40 is rotated out from the corresponding receiving slot 26. The latching portion 426 of each supporting member 40 is disengaged from the corresponding second positioning portion 264 to engage in the corresponding first positioning portion 262. At this time, the supporting members 40 are substantially perpendicular to the bottom wall 22. Therefore, the supporting members 40 can readily and stably support the chassis 20.

When the computer enclosure 100 needs to be transported or packed, each supporting member 40 is rotated into the corresponding receiving slot 26. The latching portion 426 of each supporting member 40 is disengaged from the corresponding first positioning portion 262 to engage in the corresponding second positioning portion 264. Thus, each supporting member 40 is received in the corresponding receiving slot 26 for space-saving.

In another embodiment, the latching portion 426 of each supporting member 40 may be a recess, accordingly, the first and second positioning portions 262 and 264 may be protrusions.

Even though numerous characteristics and advantages of the embodiments have been set forth in the foregoing description, together with details of the structure and function of the embodiments, the present disclosure is illustrative only, and changes may be made in details, especially in the matters of shape, size, and arrangement of parts within the principles of the embodiments to the full extent indicated by the broad general meaning of the terms in which the appended claims are expressed.

What is claimed is:

1. A computer enclosure comprising:
a chassis comprising a bottom wall, and two opposite sidewalls extending up from opposite sides of the bottom wall, a junction of the bottom wall and each sidewall defining a plurality of receiving slots, a pole extending down from a top wall of each receiving slot; and
a plurality of supporting members, an end of each supporting member rotatably mounted to a corresponding one of the poles, wherein an inner wall of each receiving slot forms a first positioning portion and a second positioning portion, a latching portion is formed on the rotating portion of each supporting member, wherein the latching portion is engaged with the first positioning portion or the second positioning portion, to respectively keep the supporting member extending out of the receiving space to support the chassis, or keep the supporting member being received in the receiving space.

2. The computer enclosure of claim 1, wherein each pole is located in an end of the corresponding receiving slot, a distal end of the pole is threaded, the rotating portion defines a stepped hole, the stepped hole comprises a first hole extending through a top surface of the supporting member, and a second hole extending through a bottom surface of the supporting member and communicating with the first hole, the pole extends through the through hole and is received in the second hole, a nut is screwed to the pole and is received in the second hole.

3. The computer enclosure of claim 1, wherein the first positioning portion is defined in a sidewall of each receiving slot, the second positioning portion is defined in an end wall of each receiving slot.

4. The computer enclosure of claim 3, wherein the first and second positioning portions are hemispherical recesses, the latching portion is a hemispherical protrusion.
